(19) United States
(12) Patent Application Publication
(10) Pub. No.: US 2016/0247908 A1
(43) Pub. Date: Aug. 25, 2016

(54) NONVOLATILE SEMICONDUCTOR MEMORY DEVICE

(71) Applicant: Kabushiki Kaisha Toshiba, Minato-ku (JP)

(72) Inventors: Ken Komiya, Yokkaichi (JP); Tetsuya Hayashi, Yokkaichi (JP); Takashi Kobayashi, Yokkaichi (JP); Yuichiro Suzuki, Yokkaichi (JP); Ryo Yougauchi, Yokkaichi (JP); Yoshitomo Hatakeyama, Yokkaichi (JP)

(73) Assignee: Kabushiki Kaisha Toshiba, Minato-ku (JP)

(21) Appl. No.: 14/838,550

(22) Filed: Aug. 28, 2015

Related U.S. Application Data
(60) Provisional application No. 62/119,648, filed on Feb. 23, 2015.

(51) Int. Cl. H01L 29/788; H01L 27/115; H01L 29/423

(52) U.S. Cl. CPC H01L 29/788; H01L 29/42328; H01L 27/11524

(57) ABSTRACT

According to an embodiment, a nonvolatile semiconductor memory device comprises: a semiconductor layer; a charge accumulation layer facing the semiconductor layer via a gate insulating layer; and a control gate electrode facing the charge accumulation layer via an inter-gate insulating layer. The charge accumulation layer comprises: a first semiconductor layer facing the semiconductor layer via the gate insulating layer; a second semiconductor layer contacting the first semiconductor layer and including carbon; and a third semiconductor layer contacting the second semiconductor layer and including carbon and boron. Concentrations of carbon and boron in the second semiconductor layer are lower than 5.0×10²¹ (cm⁻³). Concentration of carbon and boron in the third semiconductor layer are higher than 1.0×10²¹ (cm⁻³) and lower than 5.0×10²¹ (cm⁻³).

### CROSS-REFERENCE TO RELATED APPLICATIONS

This application is based upon and claims the benefit of U.S. Provisional Patent Application No. 62/119,648, filed on Feb. 23, 2015, the entire contents of which are incorporated herein by reference.

### FIELD

An embodiment described herein relates to a nonvolatile semiconductor memory device.

### BACKGROUND

### Description of the Related Art

A memory cell configuring a nonvolatile semiconductor memory device such as a NAND type flash memory includes a semiconductor layer, a control gate electrode, and a charge accumulation layer. The memory cell changes its threshold voltage according to a charge accumulated in the charge accumulation layer and stores a magnitude of this threshold voltage as data. In recent years, enlargement of capacity and raising of integration level has been proceeding in such a nonvolatile semiconductor memory device.

### BRIEF DESCRIPTION OF THE DRAWINGS

FIG. 1 is a block diagram showing a schematic configuration of a nonvolatile semiconductor memory device according to a first embodiment.

FIG. 2 is a circuit diagram showing a configuration of part of the same nonvolatile semiconductor memory device.

FIG. 3 is a schematic plan view of the same nonvolatile semiconductor memory device.

FIG. 4 is a cross-sectional view taken along the line A-A of FIG. 3.

FIG. 5 is a cross-sectional view taken along the line B-B of FIG. 3.

FIG. 6 is a schematic cross-sectional view showing a configuration of part of the same nonvolatile semiconductor memory device.

### DETAILED DESCRIPTION

A nonvolatile semiconductor memory device according to an embodiment described below comprises: a semiconductor layer; a charge accumulation layer facing the semiconductor layer via a gate insulating layer; and a control gate electrode facing the charge accumulation layer via an inter-gate insulating layer. The charge accumulation layer comprises: a first semiconductor layer facing the semiconductor layer via the gate insulating layer; a second semiconductor layer contacting the first semiconductor layer and including carbon; and a third semiconductor layer contacting the second semiconductor layer and including carbon and boron. Concentrations of carbon and boron in the second semiconductor layer are lower than 5.0×10²¹ (cm⁻³). Concentrations of carbon and boron in the third semiconductor layer are higher than 1.0×10²¹ (cm⁻³) and lower than 5.0×10²¹ (cm⁻³).

An embodiment of a nonvolatile semiconductor memory device will be described below with reference to the drawings. Note that voltage values and so on shown in the specification are merely illustrative, and may be changed appropriately.

### First Embodiment

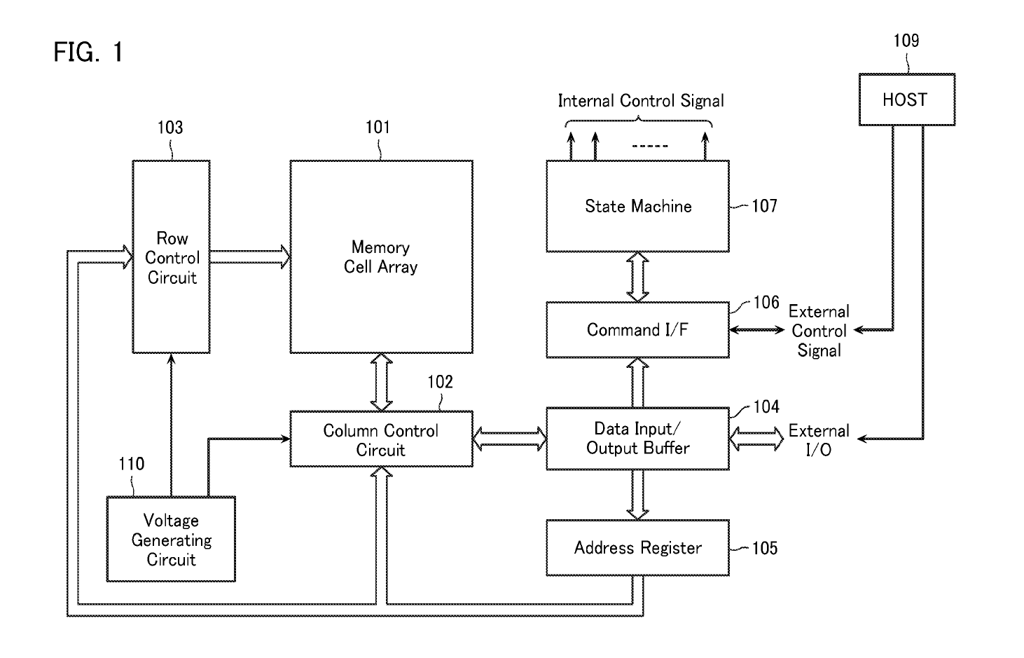

FIG. 1 is a block diagram of a nonvolatile semiconductor memory device according to a first embodiment. This nonvolatile semiconductor memory device includes a memory cell array 101 having a plurality of memory cells MC disposed substantially in a matrix therein, and comprising a bit line BL and a word line WL disposed orthogonally to each other and connected to these memory cells MC. Provided in a periphery of this memory cell array 101 are a column control circuit 102 and a row control circuit 103. The column control circuit 102 controls the bit line BL and performs data erase of the memory cell, data write to the memory cell, and data read from the memory cell. The row control circuit 103 selects the word line WL and applies a voltage for data erase of the memory cell, data write to the memory cell, and data read from the memory cell.

A data input/output buffer 104 is connected to an external host 109, via an I/O line, and receives write data, receives an erase command, outputs read data, and receives address data or command data. The data input/output buffer 104 sends received write data to the column control circuit 102, and receives data read from the column control circuit 102 to be outputted to external. An address supplied to the data input/output buffer 104 from external is sent to the column control circuit 102 and the row control circuit 103 via an address register 105.

Moreover, a command supplied to the data input/output buffer 104 from the host 109 is sent to a command interface 106. The command interface 106 receives an external control signal from the host 109, determines whether data inputted to the data input/output buffer 104 is write data or a command or an address, and, if a command, receives the data and transfers the data to a state machine 107 as a command signal.

The state machine 107 performs management of this nonvolatile memory overall, receives a command from the host 109, via the command interface 106, and performs management of read, write, erase, input/output of data, and so on.

In addition, it is also possible for the external host 109 to receive status information managed by the state machine 107 and judge an operation result. Moreover, this status information is utilized also in control of write and erase.

Furthermore, the state machine 107 controls a voltage generating circuit 110. This control enables the voltage generating circuit 110 to output a pulse of any voltage and any timing.

Now, the pulse formed by the voltage generating circuit 110 can be transferred to any wiring line selected by the column control circuit 102 and the row control circuit 103. These column control circuit 102, row control circuit 103, state machine 107, voltage generating circuit 110, and so on, configure a control circuit in the present embodiment.

[Configuration of Memory Cell Array 101]

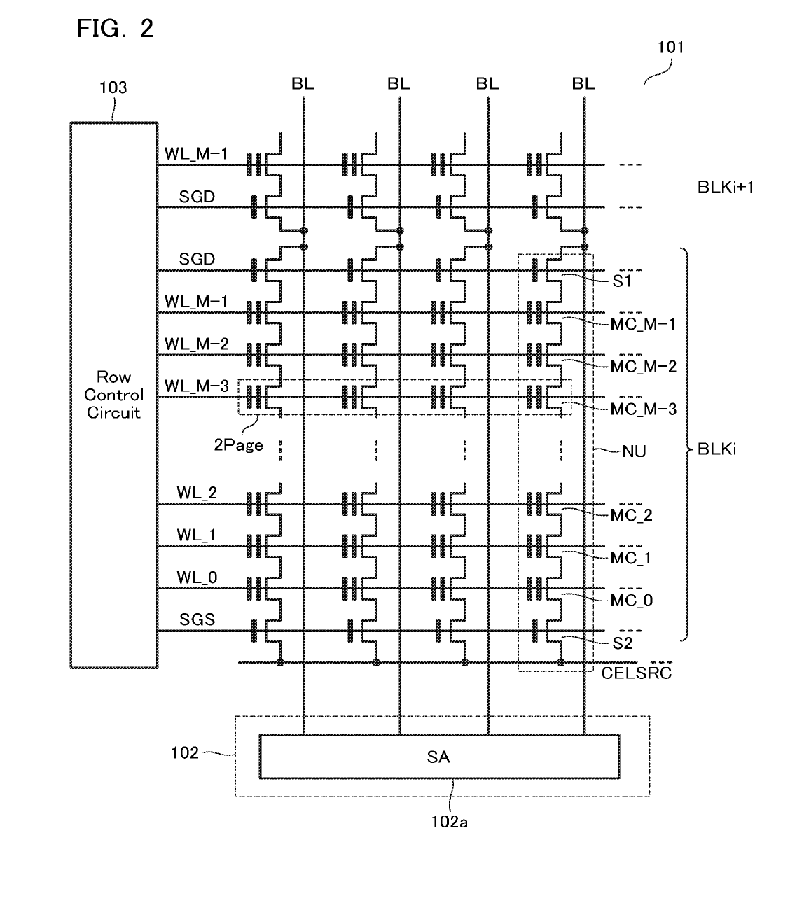

FIG. 2 is a circuit diagram showing a configuration of the memory cell array 101. As shown in FIG. 2, the memory cell array 101 is configured having NAND cell units NU arranged therein, each of the NAND cell units NU having select gate transistors S1 and S2 respectively connected to both ends of a NAND string, the NAND string having M electrically rewritable nonvolatile memory cells MC_0 to MC_M-1 connected in series therein, sharing a source and a drain.

The NAND cell unit NU has one end (a select gate transistor S1 side) connected to the bit line BL and the other end (a select gate transistor S2 side) connected to a common source line CELSRC. Gate electrodes of the select gate transistors S1 and S2 are connected to select gate lines SGD and SGS. In addition, control gate electrodes of the memory cells MC_0 to MC_M-1 are respectively connected to word lines WL_0 to WL_M-1. The bit line BL is connected to a sense amplifier 102a of the column control circuit 102, and the word lines WL_0 to WL_M-1 and select gate lines SGD and SGS are connected to the row control circuit 103.

In the case of 2 bits/cell where 2 bits of data are stored in one memory cell MC, data stored in the plurality of memory cells MC connected to one word line WL configures 2 pages (an upper page UPPER and a lower page LOWER) of data.

One block BLK is formed by the plurality of NAND cell units NU sharing the word line WL. One block BLK forms a single unit of a data erase operation. The number of word lines WL in one block BLK in one memory cell array 101 is M, and, in the case of 2 bits/cell, the number of pages in one block is M×2 pages.

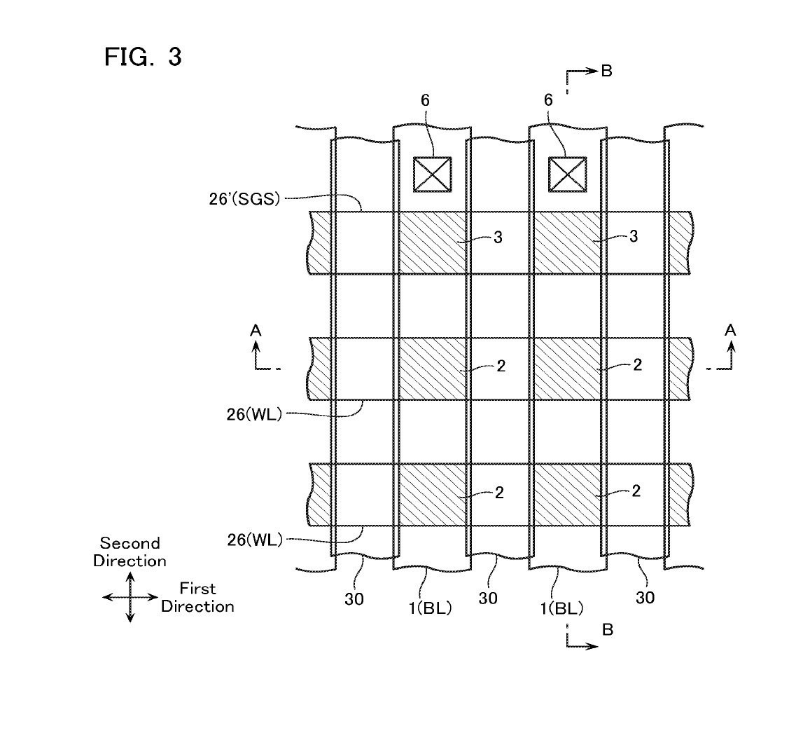

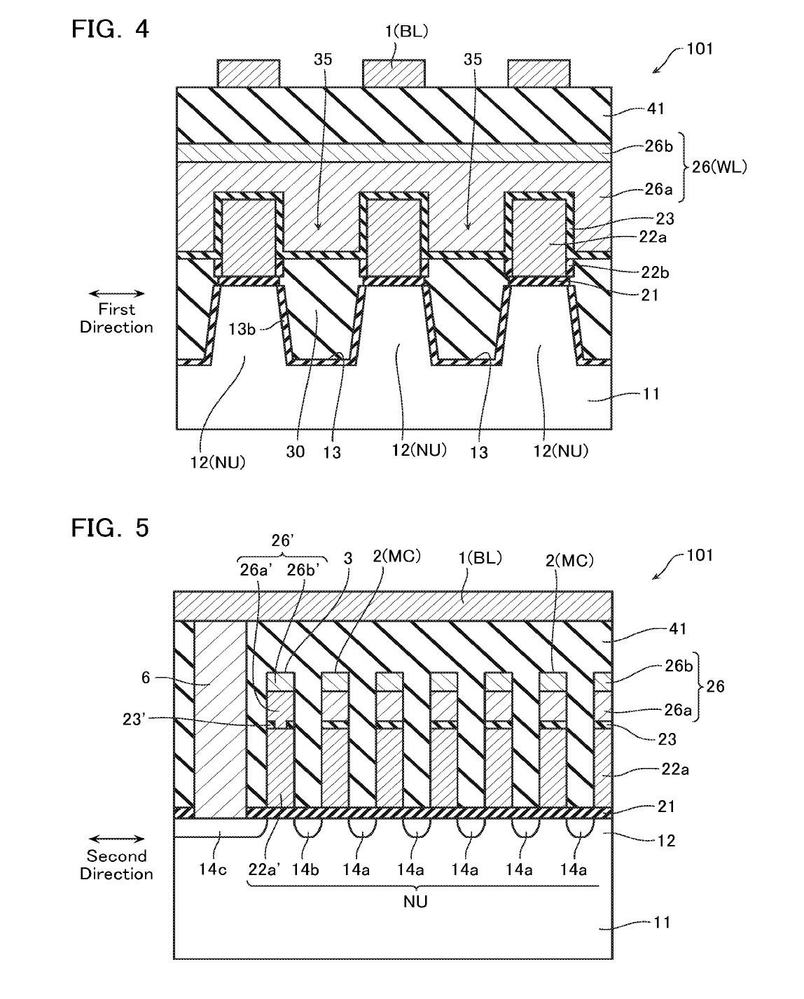

FIG. 3 is a schematic plan view of the nonvolatile semiconductor memory device according to the first embodiment; and FIGS. 4 and 5 are cross-sectional views respectively taken along the lines A-A and B-B of FIG. 3.

As shown in FIG. 3, the memory cell array of the NAND type flash memory is configured having a plurality of memory cells 2 (MC) and a select transistor 3 (S1 and S2) connected in series along a bit line 1 (BL). Moreover, a plurality of the memory cells 2 arranged in a direction of extension of a word line 26 (WL) (hereafter, called “first direction”) are connected to a common word line 26, and the select transistor 3 is connected to a common select gate line 26′ (SGS and SGD). Each of the select transistors 3 is connected to the bit line 1 via a bit line contact 6.

As shown in FIG. 4, the memory cell array includes an element formation region 12 formed on a silicon substrate 11, and this element formation region 12 is partitioned by an element isolation trench 13. As shown in FIG. 5, the memory cell 2 and the select transistor 3 are formed on this element formation region 12.

In addition, as shown in FIG. 5, the memory cells 2 adjacent in a direction of extension of the bit line 1 (hereafter, called “second direction”) share a source/drain diffusion layer 14a on the silicon substrate 11. Similarly, the memory cell 2 and the select transistor 3 adjacent in the second direction share a source/drain diffusion layer 14b on the silicon substrate 11. Moreover, the select transistors 3 facing each other sandwiching the bit line contact 6 share a source/drain diffusion layer 14c on the silicon substrate 11.

As shown in FIG. 4, formed in each of the element formation regions 12, via a first gate insulating film 21 (lower gate insulating film) which is a tunnel insulating film, is a floating gate electrode (charge accumulation layer) 22a. The floating gate electrode 22a, the first gate insulating film 21, and the element isolation trench 13 are patterned simultaneously as will be described later, hence are aligned with each other at their side surfaces. Note that a configuration of the floating gate electrode 22a will be described later.

Formed on an inner wall (bottom surface and side surfaces) of the element isolation trench 13 is an insulating film 13b, and formed on a lower side surface of the floating gate electrode 22a is an insulating film 22b. Moreover, formed on the inside of the element isolation trench 13 is an element isolation insulating film 30. Note that an upper surface of the element isolation insulating film 30 is positioned at a height between an upper surface and a lower surface of the floating gate electrode 22a.

As shown in FIG. 4, a control gate electrode 26 is pattern formed continuously straddling a plurality of the element formation regions 12 in the first direction, and configures the word line WL. Moreover, the control gate electrode 26 faces an upper surface and side surfaces of the floating gate electrode 22a via a second gate insulating film 23 (upper gate insulating film). Furthermore, the control gate electrode 26 is formed so as to be implanted to a concave portion 35 between the floating gate electrodes 22a.

The control gate electrode 26 has a two-layer structure of a polycrystalline silicon film 26a and a tungsten silicide (WSi) film 26b. Materials of the films 26a and 26b are not limited to polycrystalline silicon or tungsten silicide, and the likes of a silicide film of polysilicon, for example, may also be utilized. Note that it is also possible for the tungsten silicide film 26b to be omitted.

As shown in FIG. 5, the select transistor 3 comprises a gate electrode 22a′, an insulating film 23′, and a select gate line 26′ (films 26a′ and 26b′). The gate electrode 22a′, the insulating film 23′, and the films 26a′ and 26b′ are respectively formed by films of identical materials to those of each of portions 22a, 23, 26a, and 26b of the memory cell 2. However, the select gate line 26′ is directly connected to (short-circuited with) the gate electrode 22a′ due to the second gate insulating film 23′ being partially removed.

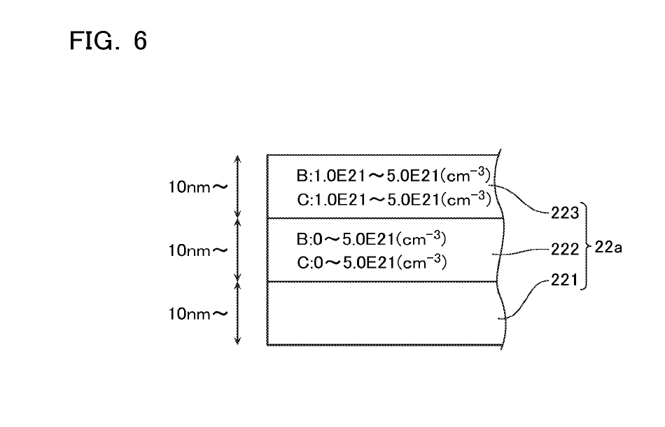

Next, the configuration of the floating gate electrode 22a according to the present embodiment will be described with reference to FIG. 6. FIG. 6 is a schematic cross-sectional view showing the configuration of the floating gate electrode 22a.

As shown in FIG. 6, the floating gate electrode 22a according to the present embodiment has the following stacked sequentially therein, namely: a first semiconductor layer 221; a second semiconductor layer 222; and a third semiconductor layer 223.

The first semiconductor layer 221 is configured from, for example, non-doped polysilicon. However, the first semiconductor layer 221 may include carbon or boron. However, a concentration of boron in the first semiconductor layer 221 is two or more powers of ten lower compared to a concentration of boron in the third semiconductor layer 223. Note that in the present embodiment, the first semiconductor layer 221 has a film thickness of 10 nm or more. However, the film thickness of the first semiconductor layer 221 is appropriately adjustable, and, for example, may also be set even larger.

The second semiconductor layer 222 is configured from, for example, polysilicon including carbon. A concentration of carbon in the second semiconductor layer 222 is lower than 5.0×10²¹ (cm⁻³). Moreover, the second semiconductor layer 222 may include boron. A concentration of boron in the second semiconductor layer 222 is lower than 5.0×10²¹ (cm⁻³). Note that in the present embodiment, the second semiconductor layer 222 has a film thickness of 10 nm or more. However, the film thickness of the second semiconductor layer 222 is appropriately adjustable, and, for example, may also be set even larger.

The third semiconductor layer 223 is configured from, for example, polysilicon including carbon and boron.

Concentrations of carbon and boron in the third semiconductor layer 223 are lower than 5.0×10²¹ (cm⁻³). Note that the third semiconductor layer 223 has a film thickness of, for example, 10 nm or more, and more preferably has a film thickness of 40 nm or more. However, the film thickness of the third semiconductor layer 223 is appropriately adjustable.

Now, when boron concentration of a portion comparatively close to the silicon substrate 11 in the floating gate electrode 22a is low, charge retention characteristics in the memory cell 2 can be improved. Moreover, when boron concentration of a portion comparatively close to the control gate electrode 26 in the floating gate electrode 22a is comparatively high, erase operation characteristics in the memory cell 2 can be improved.

However, sometimes, when a write operation or erase operation are repeated, boron within the floating gate electrode 22a ends up diffusing, leading to a lowering of charge retention characteristics and erase operation characteristics.

Accordingly, in the nonvolatile semiconductor memory device according to the present embodiment, boron concentration of the first semiconductor layer 221 is set comparatively low to enable charge retention characteristics in the memory cell 2 to be improved. Moreover, in the present embodiment, boron concentration of the third semiconductor layer 223 is set comparatively high to enable erase operation characteristics to be improved. Furthermore, in the present embodiment, the second semiconductor layer 222 configured from polysilicon including carbon is positioned between the first semiconductor layer 221 and the third semiconductor layer 223. Therefore, diffusion of boron from the third semiconductor layer 223 to the first semiconductor layer 221 can be suppressed by the carbon in the second semiconductor layer 222. In such a case, the concentration of boron in the first semiconductor layer 221 tends to be two or more powers of ten lower compared to the concentration of boron in the third semiconductor layer 223.

Furthermore, as a result of investigation by the inventors, it was found that when the concentration of carbon in the third semiconductor layer is about 1.0 to 5.0×10²¹ (cm⁻³), diffusion to the first semiconductor layer 221 of boron included in the third semiconductor layer 223 can be suitably prevented. In addition, sometimes, when the concentration of boron is less than the concentration of carbon, a concentration of holes in the third semiconductor layer 223 falls whereby it ends up being difficult to improve erase operation characteristics. Accordingly, in the present embodiment, the concentration of boron in the third semiconductor layer is set to not less than the concentration of carbon. As a result, improvement of erase characteristics can be effected, while suitably preventing diffusion to the first semiconductor layer 221 of boron included in the third semiconductor layer 223.

Note that, for example, the concentration of carbon in the second semiconductor layer 222 may be set higher than the concentration of carbon in the third semiconductor layer 223. As a result, diffusion of boron to the first semiconductor layer 221 can be more suitably suppressed.

Moreover, for example, in the second semiconductor layer 222, the concentration of carbon may be adjusted to 4.0×10²⁰ (cm⁻³), and in the third semiconductor layer 223, the concentration of carbon may be adjusted to 4.0×10²⁰ (cm⁻³) and the concentration of boron may be adjusted to 3.5×10²¹ (cm⁻³).

Moreover, for example, in the second semiconductor layer 222, the concentration of carbon may be adjusted to 7.0×10²⁰ (cm⁻³), and in the third semiconductor layer 223, the concentration of carbon may be adjusted to 4.0×10²⁰ (cm and the concentration of boron may be adjusted to 3.5×10²¹ (cm⁻³).

Moreover, for example, in the second semiconductor layer 222, the concentration of carbon may be adjusted to 1.0×10²¹ (cm⁻³), and in the third semiconductor layer 223, the concentration of carbon may be adjusted to 4.0×10²⁰ (cm⁻³) and the concentration of boron may be adjusted to 3.5×10²¹ (cm⁻³).

Moreover, for example, in the second semiconductor layer 222, the concentration of carbon may be adjusted to 1.0×10²¹ (cm⁻³), and in the third semiconductor layer 223, the concentration of carbon may be adjusted to 2.0×10²⁰ (cm⁻³) and the concentration of boron may be adjusted to 3.5×10²¹ (cm⁻³).

Moreover, for example, in the second semiconductor layer 222, the concentration of carbon may be adjusted to 1.0×10²¹ (cm⁻³), in the third semiconductor layer 223, the concentration of carbon may be adjusted to 4.0×10²⁰ (cm⁻³) and the concentration of boron may be adjusted to 3.5×10²¹ (cm⁻³), and, furthermore, the film thickness of the third semiconductor layer 223 may be adjusted to about 45 nm.

Moreover, for example, in the second semiconductor layer 222, the concentration of carbon may be adjusted to 1.0×10²¹ (cm⁻³), in the third semiconductor layer 223, the concentration of carbon may be adjusted to 2.0×10²⁰ (cm⁻³) and the concentration of boron may be adjusted to 3.5×10²¹ (cm⁻³), and, furthermore, the film thickness of the third semiconductor layer 223 may be adjusted to about 45 nm.

[Others]

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a semiconductor layer;
a charge accumulation layer facing the semiconductor layer via a gate insulating layer; and
a control gate electrode facing the charge accumulation layer via an inter-gate insulating layer,
the charge accumulation layer comprising:
a first semiconductor layer facing the semiconductor layer via the gate insulating layer;
a second semiconductor layer contacting the first semiconductor layer and including carbon; and
a third semiconductor layer contacting the second semiconductor layer and including carbon and boron,
concentrations of carbon and boron in the second semiconductor layer being lower than 5.0×10²¹ (cm⁻³), and
concentrations of carbon and boron in the third semiconductor layer being higher than 1.0×10²¹ (cm⁻³) and lower than 5.0×10²¹ (cm⁻³).

2. The nonvolatile semiconductor memory device according to claim 1, wherein
a concentration of boron in the first semiconductor layer is two or more powers of ten lower compared to the concentration of boron in the third semiconductor layer.

3. The nonvolatile semiconductor memory device according to claim 1, wherein
the concentration of carbon in the second semiconductor layer is higher compared to the concentration of carbon in the third semiconductor layer.

4. The nonvolatile semiconductor memory device according to claim 1, wherein
a film thickness of the first semiconductor layer is 10 nm or more.

5. The nonvolatile semiconductor memory device according to claim 1, wherein
a film thickness of the second semiconductor layer is 10 nm or more.

6. The nonvolatile semiconductor memory device according to claim 1, wherein
a film thickness of the third semiconductor layer is 40 nm or more.
